(19) United States
(12) Patent Application Publication
(10) Pub. No.: US 2023/0216006 A1
(43) Pub. Date: Jul. 6, 2023

(54) DISPLAY DEVICE

(71) Applicant: LG Display Co., Ltd., Seoul (KR)

(72) Inventors: Hyokang LEE, Paju-si (KR); MoonBae GEE, Paju-si (KR)

(21) Appl. No.: 17/965,557

(22) Filed: Oct. 13, 2022

(30) Foreign Application Priority Data
Dec. 31, 2021 (KR) 10-2021-0194704

(51) Int. Cl. H01L 33/62; H01L 33/10; H01L 33/38; H01L 33/50; H01L 25/075

(52) U.S. Cl. CPC H01L 33/62; H01L 33/10; H01L 33/382; H01L 33/505; H01L 25/0753

(57) ABSTRACT

According to aspects of the present disclosure, a display device includes a stretchable lower substrate; a pattern layer which is disposed on the lower substrate and is configured by a plurality of plate patterns and a plurality of line patterns; a plurality of pixels which is disposed on each of the plurality of plate patterns; and a plurality of connection lines which is disposed on each of the plurality of line patterns and connects the plurality of pixels, each of the plurality of pixels includes a light emitting diode and a driving element which drives the light emitting diode, the light emitting diode is divided into an emission area in which light is emitted and a non-emission area in which light is not emitted, a color conversion layer is disposed below the emission area of the light emitting diode, and a color transmission layer is disposed on the emission area of the light emitting diode, thereby improving the luminous efficiency of the light emitting diode.

### CROSS-REFERENCE TO RELATED APPLICATIONS

This application claims the benefit of and priority to Korean Patent Application No. 10-2021-0194704, filed on Dec. 31, 2021, in the Korean Intellectual Property Office, which is herein incorporated by reference in its entirety.

### BACKGROUND

### Technical Field

The present disclosure relates to a display device, and more particularly to a stretchable display device.

### Description of the Related Art

As display devices which are used for a monitor of a computer, a television, or a cellular phone, there are an organic light emitting display device (OLED) which is a self-emitting device, a liquid crystal display device (LCD) which requires a separate light source, and the like.

An applicable range of the display device is diversified to personal digital assistants as well as monitors of computers and televisions and a display device with a large display area and a reduced volume and weight is being studied.

Recently, a display device which is manufactured by forming a display unit, a wiring line, and the like on a flexible substrate such as plastic which is a flexible material so as to be stretchable in a specific direction and changed in various forms is getting attention as a next generation display device.

### BRIEF SUMMARY

A technical benefit to be achieved by the present disclosure is to provide a display device which increases a luminous efficiency of a light emitting diode.

Another technical benefit to be achieved by the present disclosure is to provide a display device which improves a color purity.

Objects of the present disclosure are not limited to the above-mentioned objects, and other objects, which are not mentioned above, can be clearly understood by those skilled in the art from the following descriptions.

According to some aspects of the present disclosure, a display device includes a stretchable lower substrate; a pattern layer which is disposed on the lower substrate and is configured by a plurality of plate patterns and a plurality of line patterns; a plurality of pixels which is disposed on each of the plurality of plate patterns; and a plurality of connection lines which is disposed on each of the plurality of line patterns and connects the plurality of pixels, each of the plurality of pixels includes a light emitting diode and a driving element which drives the light emitting diode, the light emitting diode is divided into an emission area in which light is emitted and a non-emission area in which light is not emitted, a color conversion layer is disposed below the emission area of the light emitting diode, and a color transmission layer is disposed on the emission area of the light emitting diode, thereby improving the luminous efficiency of the light emitting diode.

Other detailed matters of the exemplary embodiments are included in the detailed description and the drawings.

According to the present disclosure, a wavelength of light is converted by a color conversion layer to be reused to improve the luminous efficiency of the display device.

In some cases, only light of a predetermined wavelength is transmitted by a color transmission layer to improve the color purity of the light.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an example embodiment of the present disclosure;

FIG. 2 is an enlarged plan view of an active area of a display device according to an example embodiment of the present disclosure;

FIG. 3 is a cross-sectional view taken along the line of FIG. 2;

FIG. 4 is a cross-sectional view taken along the line IV-IV′ of FIG. 2;

FIG. 5 is a cross-sectional view taken along the line V-V′ of FIG. 2;

FIG. 6 is a circuit diagram of a sub pixel of a display device according to an example embodiment of the present disclosure;

FIGS. 7A and 7B are enlarged cross-sectional views of an area B illustrated in FIG. 3;

FIG. 8 is a cross-sectional view of a display device according to another example embodiment of the present disclosure; and

FIG. 9 is an enlarged cross-sectional view of an area C illustrated in FIG. 8.

### DETAILED DESCRIPTION

The advantages and features of the present disclosure, and methods for accomplishing the same will be more clearly understood from example embodiments described below with reference to the accompanying drawings. However, the present disclosure is not limited to the following example embodiments but may be implemented in various different forms. The embodiments are provided only to complete disclosure of the present disclosure and to fully provide a person with ordinary skill in the art to which the present disclosure pertains with the category of the present disclosure.

The shapes, dimensions, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is referred to as being “on” another element or layer, it may be directly on the other element or layer, or intervening elements or layers may be present.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Throughout the whole specification, the same reference numerals denote the same elements.

Since the dimensions and thickness of each component illustrated in the drawings are represented for convenience in explanation, the present disclosure is not necessarily limited to the illustrated dimensions and thickness of each component.

The features of various embodiments of the present disclosure can be partially or entirely coupled to or combined with each other and can be interlocked and operated in technically various ways, and the embodiments can be carried out independently of or in association with each other.

Hereinafter, various example embodiments of the present disclosure will be described in detail with reference to the accompanying drawings.

A display device according to an example embodiment of the present disclosure is a display device which is capable of displaying images even in a bent or extended state and may also be referred to as a display device, a flexible display device, and a stretchable display device. The display device may have not only a high flexibility, but also stretchability. Therefore, the user may bend or extend a display device and a shape of a display device may be freely changed in accordance with manipulation of a user. For example, when the user pulls the display device by holding ends of the display device, the display device may be extended to the pulling direction of the user. Alternatively, when the user disposes the display device on an outer surface which is not flat, the display device may be disposed to be bent in accordance with the shape of the outer surface of the wall. Further, when a force applied by the user is removed, the display device may return to its original shape.

### Stretchable Substrate and Pattern Layer

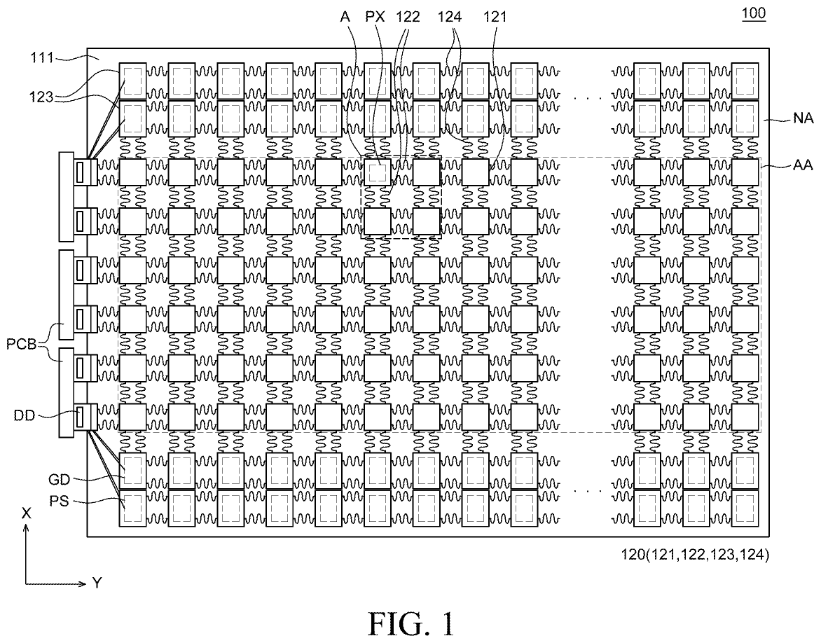

FIG. 1 is a plan view of a display device according to an example embodiment of the present disclosure.

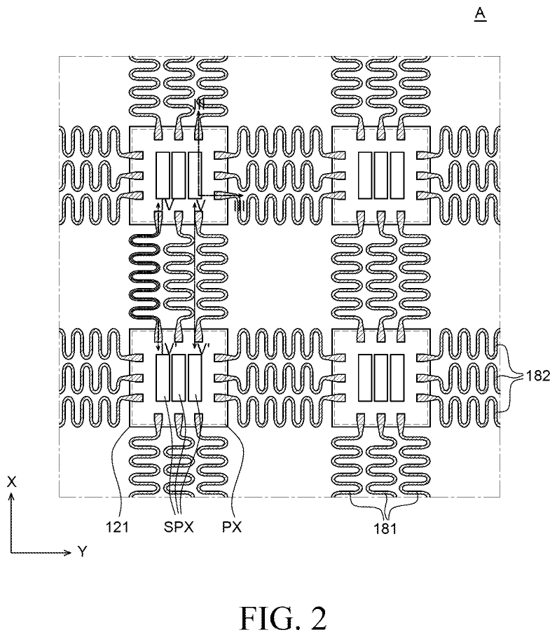

FIG. 2 is an enlarged plan view of an active area of a display device according to an example embodiment of the present disclosure.

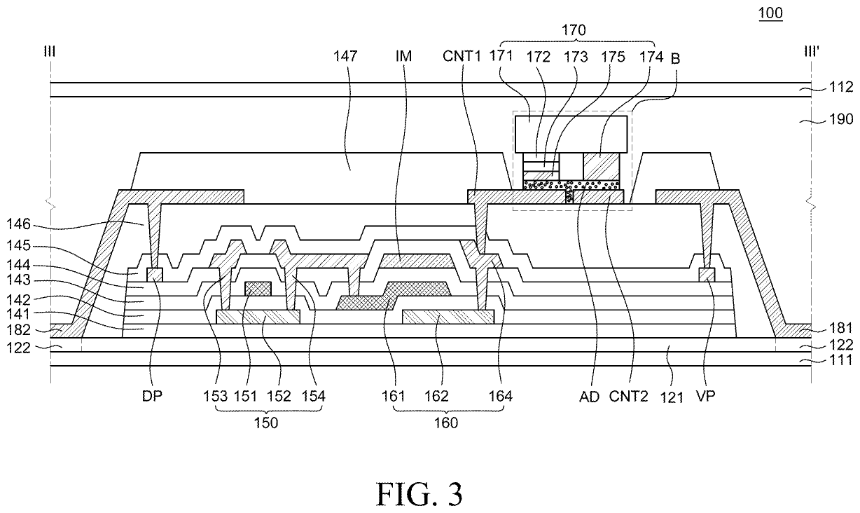

FIG. 3 is a cross-sectional view taken along the line of FIG. 2.

Specifically, FIG. 2 is an enlarged plan view of an area A illustrated in FIG. 1.

Referring to FIG. 1, a display device 100 according to an example embodiment of the present disclosure may include a lower substrate 111, a pattern layer 120, a plurality of pixels PX, a gate driver GD, a data driver DD, and a power supply PS. Referring to FIG. 1, the display device 100 according to the example embodiment of the present disclosure may further include a filling layer 190 and an upper substrate 112.

The lower substrate 111 is a substrate which supports and protects several components of the display device 100. The upper substrate 112 is a substrate which covers and protects several components of the display device 100. That is, the lower substrate 111 is a substrate which supports the pattern layer 120 on which the pixels PX, the gate driver GD, and the power supply PS are formed. The upper substrate 112 is a substrate which covers the pixels PX, the gate driver GD, and the power supply PS.

The lower substrate 111 and the upper substrate 112 which are flexible substrates may be configured by an insulating material which is bendable or extendable. For example, the lower substrate 111 and the upper substrate 112 may be formed of a silicon rubber such as polydimethylsiloxane (PDMS) or an elastomer such as polyurethane (PU) or polytetrafluoroethylene (PTFE) and thus have a flexibility. Further, the materials of the lower substrate 111 and the upper substrate 112 may be the same, but are not limited thereto and may vary.

The lower substrate 111 and the upper substrate 112 are flexible substrates so as to be reversibly expandable and contractible. Accordingly, the lower substrate 111 may be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, or a first flexible substrate. The upper substrate 112 may be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, or a second flexible substrate. Further, moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate is a stretching rate at a timing when an object to be stretched is broken or cracked. A thickness of the lower substrate may be 10 μm to 1 mm, but is not limited thereto.

The lower substrate 111 may have an active area AA and a non-active area NA which encloses the active area AA. However, the active area AA and the non-active area NA are not mentioned to be limited to the lower substrate 111, but mentioned for the entire display device.

The active area AA is an area in which images are displayed in the display device 100. The plurality of pixels PX is disposed in the active area AA. Each pixel PX may include a display element and various driving elements for driving the display element. Various driving elements may be to at least one thin film transistor (TFT) and a capacitor, but are not limited thereto. The plurality of pixels PX may be connected to various wiring lines, respectively. For example, each of the plurality of pixels PX may be connected to various wiring lines, such as a gate line, a data line, a high potential voltage line, a low potential voltage line, a reference voltage line, and an initialization voltage line.

The non-active area NA is an area where no image is displayed. The non-active area NA is an area adjacent to the active area AA. The non-active area NA may be adjacent to the active area AA to enclose the active area AA. However, it is not limited thereto so that the non-active area NA corresponds to an area excluding the active area AA from the lower substrate 111 and may be modified and separated in various forms. Components for driving the plurality of pixels PX disposed in the active area AA are disposed in the non-active area NA. That is, the gate driver GD and the power supply PS may be disposed in the non-active area NA. In the non-active area NA, a plurality of pads connected to the gate driver GD and the data driver DD may be disposed and each pad may be connected to each of the plurality of pixels PX of the active area AA.

A pattern layer 120 which includes a plurality of first plate patterns 121 and a plurality of first line patterns 122 disposed in the active area AA and a plurality of second plate patterns 123 and a plurality of second line patterns 124 disposed in the non-active area NA is disposed on the lower substrate 111.

The plurality of first plate patterns 121 is disposed in the active area AA of the lower substrate 111 so that the plurality of pixels PX is formed on the plurality of first plate patterns 121. The plurality of second plate patterns 123 may be disposed in the non-active area NA of the lower substrate 111. The gate driver GD and the power supply PS are formed on the plurality of second plate patterns 123.

The plurality of first plate patterns 121 and the plurality of second plate patterns 123 which have been described above are formed in the form of separate islands. The plurality of first plate patterns 121 and the plurality of second plate patterns 123 may be individually separated, respectively. Therefore, the plurality of first plate patterns 121 and the plurality of second plate patterns 123 may be referred to as first island patterns and second island patterns or first individual patterns and second individual patterns.

Specifically, the gate driver GD may be mounted in the plurality of second plate patterns 123. The gate driver GD may be formed on the second plate pattern 123 in a gate in panel (GIP) manner when various components on the first plate pattern 121 are manufactured. Therefore, various circuit configurations which configure the gate driver GD, such as various transistors, capacitors, and wiring lines, may be disposed on the plurality of second plate patterns 123. However, it is not limited thereto and the gate driver GD may be mounted in a chip on film (COF) manner.

The power supply PS may be mounted in the plurality of second plate patterns 123. The power supply PS is a plurality of power blocks patterned when various components on the first plate pattern 121 are manufactured and may be formed on the second plate pattern 123. Therefore, power blocks disposed on different layers may be disposed on the second plate pattern 123. That is, a lower power block and an upper power block may be sequentially disposed on the second plate pattern 123. A low potential voltage may be applied to the lower power block and a high potential voltage may be applied to the upper power block. Therefore, the low potential voltage may be supplied to the plurality of pixels PX by means of the lower power block. The high potential voltage may be supplied to the plurality of pixels PX by means of the upper power block.

Referring to FIG. 1, sizes of the plurality of second plate patterns 123 may be larger than sizes of the plurality of first plate patterns 121. Specifically, a size of each of the plurality of second plate patterns 123 may be larger than a size of each of the plurality of first plate patterns 121. As described above, the gate driver GD is disposed on each of the plurality of second plate patterns 123 and one stage of the gate driver GD may be disposed in each of the plurality of second plate patterns 123. Therefore, an area occupied by various circuit configurations which configure one stage of the gate driver GD may be relatively larger than an area occupied by the pixel PX so that a size of each of the plurality of second plate patterns 123 may be larger than a size of each of the plurality of first plate patterns 121.

Even though in FIG. 1, the plurality of second plate patterns 123 is disposed on both sides of the non-active area NA in the first direction X, but it is not limited thereto and may be disposed in an arbitrary area of the non-active area NA. Further, even though it is illustrated that the plurality of first plate patterns 121 and the plurality of second plate patterns 123 have a quadrangular shape, but it is not limited thereto and the shapes of the plurality of first plate patterns 121 and the plurality of second plate patterns 123 may vary in various forms.

Referring to FIGS. 1 and 3, the pattern layer 120 may further include the plurality of first line patterns 122 disposed in the active area AA and the plurality of second line patterns 124 disposed in the non-active area NA.

The plurality of first line patterns 122 is patterns which are disposed in the active area AA and connect the first plate patterns 121 which are adjacent to each other and is referred to as first connection patterns. That is, the plurality of first line patterns 122 is disposed between the plurality of first plate patterns 121.

The plurality of second line patterns 124 is patterns which are disposed in the non-active area NA and connect the first plate patterns 121 and the second plate patterns 123 which are adjacent to each other or connect a plurality of second plate patterns 123 which is adjacent to each other. Accordingly, the plurality of second line patterns 124 may be referred to as second connection patterns. The plurality of second line patterns 124 may be disposed between the first plate pattern 121 and the second plate pattern 123 which are adjacent to each other and between the plurality of second plate patterns 123 which is adjacent to each other.

Referring to FIG. 1, the plurality of first line patterns 122 and second line patterns 124 have a wavy shape. For example, the plurality of first line patterns 122 and second line patterns 124 have a sinusoidal shape. However, the shapes of the plurality of first line patterns 122 and second line patterns 124 are not limited thereto. For example, the plurality of first line patterns 122 and second line patterns 124 may extend in a zigzag pattern. Alternatively, the plurality of first line patterns 122 and second line patterns 124 may be formed with various shapes such as a shape extended by connecting a plurality of rhombus-shaped substrates at vertexes. Further, the number and the shape of the plurality of first line patterns 122 and second line patterns 124 illustrated in FIG. 1 are examples and may be changed in various forms depending on the design.

The plurality of first plate patterns 121, the plurality of first line patterns 122, the plurality of second plate patterns 123, and the plurality of second line patterns 124 are rigid patterns. That is, the plurality of first plate patterns 121, the plurality of first line patterns 122, the plurality of second plate patterns 123, and the plurality of second line patterns 124 may be rigider than the lower substrate 111 and the upper substrate 112. That is, moduli of elasticity of the plurality of first plate patterns 121, the plurality of first line patterns 122, the plurality of second plate patterns 123, and the plurality of second line patterns 124 may be higher than a modulus of elasticity of the lower substrate 111. The modulus of elasticity is a parameter representing a rate of deformation against the stress applied to the substrate and the higher the modulus of elasticity, the higher the hardness. Therefore, the plurality of first plate patterns 121, the plurality of first line patterns 122, the plurality of second plate patterns 123, and the plurality of second line patterns 124 may be referred to as a plurality of first rigid patterns, a plurality of second rigid patterns, a plurality of third rigid patterns, and a plurality of fourth rigid patterns, respectively. Moduli of elasticity of the plurality of first plate patterns 121, the plurality of first line patterns 122, the plurality of second plate patterns 123, and the plurality of second line patterns 124 may be 1000 times or higher than the moduli of elasticity of the lower substrate 111 and the upper substrate 112, but is not limited thereto.

The plurality of first plate patterns 121, the plurality of first line patterns 122, the plurality of second plate patterns 123, and the plurality of second line patterns 124 which are a plurality of rigid substrates may be formed of a plastic material having a flexibility lower than that of the lower substrate 111 and the upper substrate 112. For example, the plurality of first plate patterns 121, the plurality of first line patterns 122, the plurality of second plate patterns 123, and the plurality of second line patterns 124 may be formed of polyimide (PI), polyacrylate, polyacetate, or the like. At this time, the plurality of first plate patterns 121, the plurality of first line patterns 122, the plurality of second plate patterns 123, and the plurality of second line patterns 124 may be formed of the same material, but are not limited thereto and may be formed of different materials. When the plurality of first plate patterns 121, the plurality of first line patterns 122, the plurality of second plate patterns 123, and the plurality of second line patterns 124 are formed of the same material, the patterns may be integrally formed.

In some example embodiments, the lower substrate 111 may be defined to include a plurality of first lower patterns and second lower patterns. The plurality of first lower patterns may be an area of the lower substrate 111 overlapping the plurality of first plate patterns 121 and the plurality of second plate patterns 123. The second lower pattern may be an area which does not overlap the plurality of first plate patterns 121 and the plurality of second plate patterns 123.

Further, the upper substrate 112 may be defined to include a plurality of first upper patterns and a second upper pattern. The plurality of first upper patterns may be an area of the upper substrate 112 overlapping the plurality of first plate patterns 121 and the plurality of second plate patterns 123. The second upper pattern may be an area which does not overlap the plurality of first plate patterns 121 and the plurality of second plate patterns 123.

At this time, moduli of elasticity of the plurality of first lower patterns and the first upper pattern may be higher than moduli of elasticity of the second lower pattern and the second upper pattern. For example, the plurality of first lower patterns and the first upper pattern may be formed of the same material as the plurality of first plate patterns 121 and the plurality of second plate patterns 123. The second lower pattern and the second upper pattern may be formed of a material having a modulus of elasticity lower than those of the plurality of first plate patterns 121 and the plurality of second plate patterns 123.

That is, the first lower pattern and the first upper pattern may be formed of polyimide (PI), polyacrylate, polyacetate, or the like. Further, the second lower pattern and the second upper pattern may be formed of a silicon rubber such as polydimethylsiloxane (PDMS) or an elastomer such as polyurethane (PU) or polytetrafluoroethylene (PTFE).

### Driving Element of Non-Active Area

The gate driver GD is a component which supplies a gate voltage to the plurality of pixels PX disposed in the active area AA. The gate driver GD includes a plurality of stages formed on the plurality of second plate patterns 123 and each stage of the gate driver GD may be electrically connected to each other by means of the plurality of gate connection lines. Accordingly, a gate voltage output from any one of the stages may be transmitted to the other stage. Each stage may sequentially supply the gate voltage to the plurality of pixels PX connected to each stage.

The power supply PS is connected to the gate driver GD to supply a gate driving voltage and a gate clock voltage. The power supply PS is connected to the plurality of pixels PX to supply a pixel driving voltage to each of the plurality of pixels PX. The power supply PS may also be formed on the plurality of second plate patterns 123. That is, the power supply PS may be formed to be adjacent to the gate driver GD on the second plate pattern 123. Power supplies PS formed on the plurality of second plate patterns 123 may be electrically connected to the gate driver GD and the plurality of pixels PX. That is, the plurality of power supplies PS formed on the plurality of second plate patterns 123 may be connected by a gate power supply connection line and a pixel power supply connection line. Therefore, each of the plurality of power supplies PS may supply a gate driving voltage, a gate clock voltage, and a pixel driving voltage.

The printed circuit board PCB is a component which transmits signals and voltages for driving the display element from the control unit (or control circuit) to the display element. Therefore, the printed circuit board PCB may also be referred to as a driving substrate. A control unit such as an IC chip or a circuit unit may be mounted on the printed circuit board PCB. Further, on the printed circuit board PCB, a memory, a processor, or the like may also be mounted. The printed circuit board PCB provided in the display device 100 may include a stretching area and a non-stretching area to ensure stretchability. In the non-stretching area, an IC chip, a circuit unit (or circuit), a memory, a processor, and the like may be mounted and in the stretching area, wiring lines which are electrically connected to the IC chip, the circuit unit, the memory, and the processor may be disposed.

The data driver DD is a component which supplies a data voltage to the plurality of pixels PX disposed in the active area AA. The data driver DD may be configured as an IC chip so that it may also be referred to as a data integrated circuit D-IC. The data driver DD may be mounted in the non-stretching area of the printed circuit board PCB. That is, the data driver DD may be mounted on the printed circuit board PCB in the form of a chip on board (COB). However, even though in FIG. 1, it is illustrated that the data driver DD is mounted in a chip on film (COF) manner, it is not limited thereto and the data driver DD may be mounted by a chip on board (COB), a chip on glass (COG), or a tape carrier package (TCP) manner.

Further, even though in FIG. 1, one data driver DD is disposed so as to correspond to the first plate pattern 121 in one line disposed in the active area AA, it is not limited thereto. That is, one data driver DD may be disposed so as to correspond to the first plate patterns 121 in a plurality of columns.

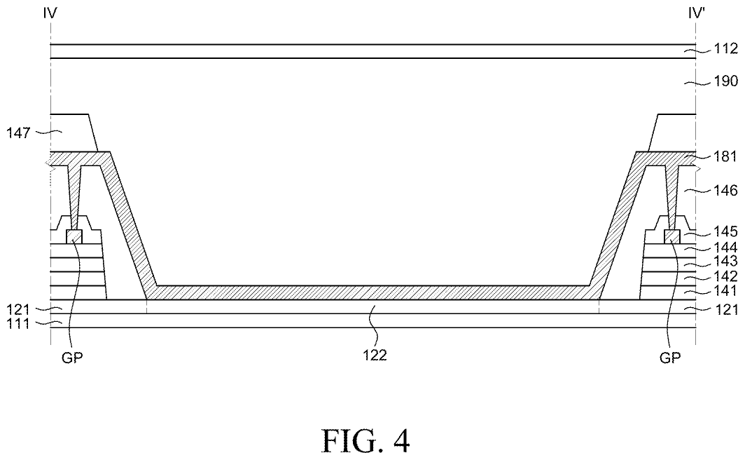

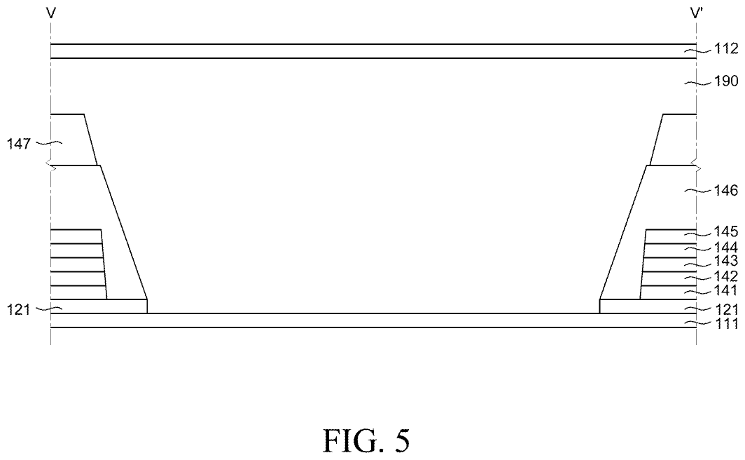

Hereinafter, the active area AA of the display device 100 according to the example embodiment of the present disclosure may be described in more detail with reference to FIGS. 4 and 5 together.

### Planar and Cross-Sectional Structures of Active Area

FIG. 4 is a cross-sectional view taken along the line IV-IV′ of FIG. 2.

FIG. 5 is a cross-sectional view taken along the line V-V′ of FIG. 2.

For the convenience of description, the description may be made with reference to FIGS. 1 to 3 together.

Referring to FIGS. 1 and 2, the plurality of first plate patterns 121 is disposed on the lower substrate 111 in the active area AA. The plurality of first plate patterns 121 is spaced apart from each other to be disposed on the lower substrate 111. For example, as illustrated in FIG. 1, the plurality of first plate patterns 121 may be disposed on the lower substrate 111 in a matrix, but is not limited thereto.

Referring to FIGS. 2 and 3, a pixel PX including the plurality of sub pixels SPX is disposed in the first plate pattern 121. Each sub pixel SPX may include an LED 170 which is a display element and a driving transistor 160 and a switching transistor 150 which drive the LED 170. However, in the sub pixel SPX, the display element is not limited to LED, and may also be changed to an organic light emitting diode. Further, the plurality of sub pixels SPX may include a red sub pixel, a green sub pixel, and a blue sub pixel, but is not limited thereto and colors of the plurality of sub pixels SPX may be modified to various colors as needed.

The plurality of sub pixels SPX may be connected to the plurality of connection lines 181 and 182. That is, the plurality of sub pixels SPX may be electrically connected to the first connection line 181 extending in the first direction X. The plurality of sub pixels SPX may be electrically connected to the second connection line 182 extending in the second direction Y.

Hereinafter, a cross-sectional structure of the active area AA will be described in detail with reference to FIG. 3.

Referring to FIG. 3, a plurality of inorganic insulating layers is disposed on the plurality of first plate patterns 121. For example, the plurality of inorganic insulating layers may include a buffer layer 141, a gate insulating layer 142, a first interlayer insulating layer 143, a second interlayer insulating layer 144, and a passivation layer 145, but is not limited thereto. Therefore, on the plurality of first plate patterns 121, various inorganic insulating layers may be additionally disposed or one or more of the buffer layer 141, the gate insulating layer 142, the first interlayer insulating layer 143, the second interlayer insulating layer 144, and the passivation layer 145 may be omitted.

Specifically, the buffer layer 141 is disposed on the plurality of first plate patterns 121. The buffer layer 141 is formed on the plurality of first plate patterns 121 to protect various components of the display device 100 from permeation of moisture (H₂O) and oxygen (O₂) from the outside of the lower substrate 111 and the plurality of first plate patterns 121. The buffer layer 141 may be configured by an insulating material. For example, the buffer layer 141 may be configured by a single layer or a double layer formed of at least one of silicon nitride (SiNx), silicon oxide (SiOx), and silicon oxynitride (SiON). However, the buffer layer 141 may be omitted depending on a structure or a characteristic of the display device 100.

At this time, the buffer layer 141 may be formed only in an area where the lower substrate 111 overlaps the plurality of first plate patterns 121 and the plurality of second plate patterns 123. As described above, the buffer layer 141 may be formed of an inorganic material so that the buffer layer 141 may be easily cracked or damaged during a process of stretching the display device 100. Therefore, the buffer layer 141 is not formed in an area between the plurality of first plate patterns 121 and the plurality of second plate patterns 123. Instead, the buffer layer 141 is patterned to have a shape of the plurality of first plate patterns 121 and the plurality of second plate patterns 123 to be disposed only above the plurality of first plate patterns 121 and the plurality of second plate patterns 123. Therefore, in the display device 100 according to the example embodiment of the present disclosure, the buffer layer 141 is formed only in an area overlapping the plurality of first plate patterns 121 and the plurality of second plate patterns 123 which are rigid patterns. Therefore, even though the display device 100 is bent or extended to be deformed, the damage to various components of the display device 100 may be suppressed.

Referring to FIG. 3, a switching transistor 150 including a gate electrode 151, an active layer 152, a source electrode 153, and a drain electrode 154 and a driving transistor 160 including a gate electrode 161, an active layer 162, a source electrode and a drain electrode 164 are formed on the buffer layer 141.

First, referring to FIG. 1, the active layer 152 of the switching transistor 150 and the active layer 162 of the driving transistor 160 are disposed on the buffer layer 141. For example, each of the active layer 152 of the switching transistor 150 and the active layer 162 of the driving transistor 160 may be formed of oxide semiconductors. For example, the active layer 152 may be formed of indium-gallium-zinc oxide, indium-gallium oxide, or indium-zinc oxide. Alternatively, the active layer 152 of the switching transistor 150 and the active layer 162 of the driving transistor 160 may be formed of amorphous silicon (a-Si), polycrystalline silicon (poly-Si), an organic semiconductor, or the like.

The gate insulating layer 142 is disposed on the active layer 152 of the switching transistor 150 and the active layer 162 of the driving transistor 160. The gate insulating layer 142 is a layer which electrically insulates the gate electrode 151 of the switching transistor 150 from the active layer 152 of the switching transistor 150 and electrically insulates the gate electrode 161 of the driving transistor 160 from the active layer 162 of the driving transistor 160. The gate insulating layer 142 may be formed of an insulating material. For example, the gate insulating layer 142 may be configured by a single layer of silicon nitride (SiNx) or silicon oxide (SiOx) which is an inorganic material or a multi-layer of silicon nitride (SiNx) or silicon oxide (SiOx), but it is not limited thereto.

The gate electrode 151 of the switching transistor 150 and the gate electrode 161 of the driving transistor 160 are disposed on the gate insulating layer 142. The gate electrode 151 of the switching transistor 150 and the gate electrode 161 of the driving transistor 160 are disposed on the gate insulating layer 142 to be spaced apart from each other. The gate electrode 151 of the switching transistor 150 overlaps the active layer 152 of the switching transistor 150 and the gate electrode 161 of the driving transistor 160 overlaps the active layer 162 of the driving transistor 160.

The gate electrode 151 of the switching transistor 150 and the gate electrode 161 of the driving transistor 160 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multi-layer thereof, but it is not limited thereto.

The first interlayer insulating layer 143 is disposed on the gate electrode 151 of the switching transistor 150 and the gate electrode 161 of the driving transistor 160. The first interlayer insulating layer 143 insulates the gate electrode 161 of the driving transistor 160 from an intermediate metal layer IM. The first interlayer insulating layer 143 may be formed of an inorganic material, similarly to the buffer layer 141. For example, the first interlayer insulating layer 143 may be configured by a single layer of silicon nitride (SiNx) or silicon oxide (SiOx) which is an inorganic material or a multi-layer of silicon nitride (SiNx) or silicon oxide (SiOx), but it is not limited thereto.

The intermediate metal layer IM is disposed on the first interlayer insulating layer 143. The intermediate metal layer IM overlaps the gate electrode 161 of the driving transistor 160. Therefore, a storage capacitor is formed in an overlapping area of the intermediate metal layer IM and the gate electrode 161 of the driving transistor 160. Specifically, the gate electrode 161 of the driving transistor 160, the first interlayer insulating layer 143, and the intermediate metal layer IM form the storage capacitor. However, the placement area of the intermediate metal layer IM is not limited thereto and the intermediate metal layer IM overlaps the other electrode to form the storage capacitor in various forms.

The intermediate metal layer IM may be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a multi-layer thereof, but it is not limited thereto.

The second interlayer insulating layer 144 is disposed on the intermediate metal layer IM. The second interlayer insulating layer 144 insulates the gate electrode 151 of the switching transistor 150 from the source electrode 153 and the drain electrode 154 of the switching transistor 150. The second interlayer insulating layer 144 insulates the intermediate metal layer IM from the source electrode and the drain electrode 164 of the driving transistor 160. The second interlayer insulating layer 144 may be formed of an inorganic material, similarly to the buffer layer 141. For example, the first interlayer insulating layer 143 may be configured by a single layer of silicon nitride (SiNx) or silicon oxide (SiOx) which is an inorganic material or a multi-layer of silicon nitride (SiNx) or silicon oxide (SiOx), but it is not limited thereto.

The source electrode 153 and the drain electrode 154 of the switching transistor 150 are disposed on the second interlayer insulating layer 144. The source electrode and the drain electrode 164 of the driving transistor 160 are disposed on the second interlayer insulating layer 144. The source electrode 153 and the drain electrode 154 of the switching transistor 150 are disposed on the same layer to be spaced apart from each other. Even though in FIG. 1, the source electrode of the driving transistor 160 is omitted, the source electrode of the driving transistor 160 is also disposed to be spaced apart from the drain electrode 164 on the same layer. In the switching transistor 150, the source electrode 153 and the drain electrode 154 may be in contact with the active layer 152 to be electrically connected to the active layer 152. In the driving transistor 160, the source electrode and the drain electrode 164 may be in contact with the active layer 162 to be electrically connected to the active layer 162. The drain electrode 154 of the switching transistor 150 is in contact with the gate electrode 161 of the driving transistor 160 through a contact hole to be electrically connected to the gate electrode 161 of the driving transistor 160.

The source electrode 153 and the drain electrodes 154 and 164 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multi-layer thereof, but it is not limited thereto.

Further, in this specification, even though it is described that the driving transistor 160 has a coplanar structure, various transistors such as a staggered structure may also be used. Further, in this specification, the transistor may be formed not only to have a top gate structure, but also to have a bottom gate structure.

A gate pad GP and a data pad DP may be disposed on the second interlayer insulating layer 144.

Specifically, referring to FIG. 4, the gate pad GP is a pad which transmits a gate voltage to the plurality of sub pixels SPX. The gate pad GP is connected to the first connection line 181 through a contact hole. The gate voltage supplied from the first connection line 181 may be transmitted to the gate electrode 151 of the switching transistor 150 from the gate pad GP through a wiring line formed on the first plate pattern 121.

Referring to FIG. 2, the data pad DP is a pad which transmits a data voltage to the plurality of sub pixels SPX. The data pad DP is connected to the second connection line 182 through a contact hole. The data voltage supplied from the second connection line 182 may be transmitted to the source electrode 153 of the switching transistor 150 from the data pad DP through a wiring line formed on the first plate pattern 121.

Referring to FIG. 3, the voltage pad VP is a pad which transmits a low potential voltage to the plurality of sub pixels SPX. The voltage pad VP is connected to the first connection line 181 through a contact hole. The low potential voltage supplied from the first connection line 181 may be transmitted to the n-electrode 174 of the LED 170 from the voltage pad VP through a second contact pad CNT2 formed on the first plate pattern 121.

The voltage pad VP, the gate pad GP, and the data pad DP may be formed of the same material as the source electrode 153 and the drain electrodes 154 and 164, but are not limited thereto.

Referring to FIG. 1, the passivation layer 145 is formed on the switching transistor 150 and the driving transistor 160. That is, the passivation layer 145 covers the switching transistor 150 and the driving transistor 160 to protect the switching transistor 150 and the driving transistor 160 from the permeation of moisture and oxygen. The passivation layer 145 may be formed of an inorganic material and configured by a single layer or a double layer, but is not limited thereto.

The gate insulating layer 142, the first interlayer insulating layer 143, the second interlayer insulating layer 144, and the passivation layer 145 are patterned to be formed only in an area overlapping the plurality of first plate patterns 121. The gate insulating layer 142, the first interlayer insulating layer 143, the second interlayer insulating layer 144, and the passivation layer 145 may also be formed of the inorganic material, similarly to the buffer layer 141. Therefore, the gate insulating layer 142, the first interlayer insulating layer 143, the second interlayer insulating layer 144, and the passivation layer 145 may also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of first plate patterns 121. However, the gate insulating layer 142, the first interlayer insulating layer 143, the second interlayer insulating layer 144, and the passivation layer 145 are patterned to have a shape of the plurality of first plate patterns 121 to be formed only above the plurality of first plate patterns 121.

The planarization layer 146 is formed on the passivation layer 145. The planarization layer 146 planarizes upper portions of the switching transistor 150 and the driving transistor 160. The planarization layer 146 may be configured by a single layer or a plurality of layers and may be formed of an organic material. Therefore, the planarization layer 146 may also be referred to as an organic insulating layer. For example, the planarization layer 146 may be formed of an acrylic organic material, but is not limited thereto.

Referring to FIG. 3, the planarization layer 146 may be disposed so as to cover top surfaces and side surfaces of the buffer layer 141, the gate insulating layer 142, the first interlayer insulating layer 143, the second interlayer insulating layer 144, and the passivation layer 145 on the plurality of first plate patterns 121. The planarization layer 146 encloses the buffer layer 141, the gate insulating layer 142, the first interlayer insulating layer 143, the second interlayer insulating layer 144, and the passivation layer 145 together with the plurality of first plate patterns 121. Specifically, the planarization layer 146 may be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of first plate patterns 121. Therefore, the planarization layer 146 may compensate for a step on the side surfaces of the buffer layer 141, the gate insulating layer 142, the first interlayer insulating layer 143, the second interlayer insulating layer 144, and the passivation layer 145. Further, the planarization layer 146 enhances an adhesive strength of the planarization layer 146 and the connection lines 181 and 182 disposed on the side surface of the planarization layer 146.

Referring to FIG. 3, an inclination angle of the side surface of the planarization layer 146 may be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 may have a slope which is gentler than a slope formed by the side surface of the passivation layer 145, the side surface of the first interlayer insulating layer 143, the side surface of the second interlayer insulating layer 144, the side surface of the gate insulating layer 142, and the side surface of the buffer layer 141. Therefore, the connection lines 181 and 182 which are disposed to be in contact with the side surface of the planarization layer 146 are disposed with a gentle slope so that when the display device 100 is stretched, the stress generated in the connection lines 181 and 182 may be reduced. Further, the side surface of the planarization layer 146 has a relatively gentle slope so that the crack of the connection lines 181 and 182 or separation thereof from the side surface of the planarization layer 146 may be suppressed.

Referring to FIGS. 2 to 4, the connection lines 181 and 182 refer to wiring lines which electrically connect the pads on the plurality of first plate patterns 121. The plurality of connection lines 181 and 182 are disposed on the plurality of first line patterns 122. As described above, the plurality of connection lines 181 and 182 disposed on the first line pattern 122 may also extend onto the plurality of first plate patterns 121 to be electrically connected to the gate pad GP and the data pad DP on the plurality of first plate patterns 121. Referring to FIG. 1, the first line pattern 122 is not disposed in an area where the connection lines 181 and 182 are not disposed, among areas between the plurality of first plate patterns 121.

The connection lines 181 and 182 include a first connection line 181 and a second connection line 182. The first connection line 181 and the second connection line 182 are disposed between the plurality of first plate patterns 121. Specifically, the first connection line 181 is a wiring line extending in the X-axis direction between the plurality of first plate patterns 121, among the connection lines 181 and 182. The second connection line 182 is a wiring line extending in the Y-axis direction between the plurality of first plate patterns 121, among the connection lines 181 and 182.

The connection lines 181 and 182 may be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a display panel of a general display device, various wiring lines such as a plurality of gate lines and a plurality of data lines extend between the plurality of sub pixels in a straight line, and the plurality of sub pixels is connected to one signal line. Therefore, in the display panel of the general display device, various wiring lines, such as a gate line, a data line, a high potential voltage line, and a reference voltage line, extend from one side to the other side of the display panel of the organic light emitting display device without being disconnected on the substrate.

In contrast, in the display device 100 according to the example embodiment of the present disclosure, various wiring lines, such as a gate line, a data line, a high potential voltage line, a reference voltage line, and an initialization voltage line having a straight line shape which are considered to be used for the display panel of the general organic light emitting display device, may be disposed only on the plurality of first plate patterns 121 and the plurality of second plate patterns 123. That is, in the display device 100 according to the example embodiment of the present disclosure, a linear wiring line may be disposed only on the plurality of first plate patterns 121 and the plurality of second plate patterns 123.

In the display device 100 according to the example embodiment of the present disclosure, the pads on the two adjacent first plate patterns 121 may be connected by the connection lines 181 and 182. Accordingly, the connection lines 181 and 182 electrically connect the gate pads GP or the data pads DP on two adjacent first plate patterns 121. Accordingly, the display device 100 according to the example embodiment of the present disclosure may include a plurality of connection lines 181 and 182 which electrically connects various wiring lines, such as a gate line, a data line, a high potential voltage line, and a reference voltage line, between the plurality of first plate patterns 121. For example, the gate line may be disposed on the plurality of first plate patterns 121 disposed to be adjacent to each other in the first direction X and the gate pad GP may be disposed on both ends of the gate line. In this case, the plurality of gate pads GP on the plurality of first plate patterns 121 adjacent to each other in the first direction X may be connected to each other by the first connection line 181 which serves as a gate line. Therefore, the gate line disposed on the plurality of first plate patterns 121 and the first connection line 181 disposed on the second plate pattern 123 may serve as one gate line. The above-described gate line may be referred to as a scan signal line. Further, wiring lines which extend in the first direction X, among all various wiring lines which may be included in the display device 100, such as an emission signal line, a low potential voltage line, and a high potential voltage line, may also be electrically connected by the first connection line 181, as described above.

Referring to FIGS. 2 and 4, the first connection lines 181 may connect the gate pads GP to each other on two first plate patterns 121 which are disposed side by side, among the gate pads GP on the plurality of first plate patterns 121 disposed to be adjacent in the first direction X. The first connection line 181 may serve as a gate line, an emission signal line, a high potential voltage line, or a low potential voltage line, but is not limited thereto. For example, the first connection line 181 may serve as a gate line and electrically connect the gate pads GP on two first plate patterns 121 which are disposed side by side in the first direction X. Therefore, as described above, the gate pads GP on the plurality of first plate patterns 121 disposed in the first direction X may be connected by the first connection line 181 serving as a gate line and transmit one gate voltage.

Referring to FIG. 2, the second connection line 182 may connect the data pads DP to each other on two first plate patterns 121 which are disposed side by side, among the data pads DP on the plurality of first plate patterns 121 disposed to be adjacent in the second direction Y. The second connection line 182 may serve as a data line, a high potential voltage line, a low potential voltage line, or a reference voltage line, but is not limited thereto. For example, the second connection line 182 may serve as a data line and electrically connect the data line on two first plate patterns 121 which are disposed side by side in the second direction Y. Therefore, as described above, the internal line on the plurality of first plate patterns 121 disposed in the second direction Y may be connected by the plurality of second connection lines 182 serving as a data line and transmit one data voltage.

As illustrated in FIG. 4, the first connection line 181 may be formed to extend to a top surface of the first line pattern 122 while being in contact with a top surface and a side surface of the planarization layer 146 disposed on the first plate pattern 121. Further, as illustrated in FIG. 1, the second connection line 182 may be formed to extend to a top surface of the first line pattern 122 while being in contact with a top surface and a side surface of the planarization layer 146 disposed on the first plate pattern 121.

However, as illustrated in FIG. 5, there is no need to dispose a rigid pattern in an area where the first connection line 181 and the second connection line 182 are not disposed. Therefore, the first line pattern which is a rigid pattern is not disposed below the first connection line 181 and the second connection line 182.

In the meantime, referring to FIG. 3, a bank 247 is formed on the first connection pad CNT1, the connection lines 181 and 182, and the planarization layer 146. The bank 247 is a component which divides adjacent sub pixels SPX. The bank 247 is disposed so as to cover at least a part of the first connection pad CNT1, the connection lines 181 and 182, and the planarization layer 146. The bank 247 may be formed of an insulating material. Further, the bank 247 may include a black material. The bank 247 includes the black material to block wiring lines which may be visible through the active area AA. For example, the bank 247 may be formed of a transparent carbon-based mixture and specifically, include carbon black. However, it is not limited thereto and the bank 247 may be formed of a transparent insulating material. Even though in FIG. 1, it is illustrated that a height of the bank 247 is lower than a height of the LED 170, the present disclosure is not limited thereto and the height of the bank 247 may be equal to the height of the LED 170.

Referring to FIG. 3, an LED 170 is disposed on the first connection pad CNT1 and the second connection pad CNT2.

The first connection pad CNT1 is electrically connected to the drain electrode 164 of the driving transistor 160 to be applied with a driving voltage from the driving transistor 160 to drive the LED 170. Even though in FIG. 3, it is illustrated that the first connection pad CNT1 is in direct contact with the drain electrode 164 of the driving transistor 160, the present disclosure is not limited thereto. Therefore, the first connection pad CNT1 and the drain electrode 164 of the driving transistor 160 may not be in direct contact with each other, but may be indirectly connected. Further, a low potential driving voltage is applied to the second connection pad CNT2 to drive the LED 170. Therefore, when the display device 100 is turned on, different voltage levels applied to the first connection pad CNT1 and the second connection pad CNT2 are transmitted to the LED 170 so that the LED 170 emits light.

The upper substrate 112 is a substrate which supports various components disposed below the upper substrate 112. Specifically, the upper substrate 112 may be formed by coating and curing a material which configures the upper substrate 112 on the lower substrate 111 and the first plate pattern 121. The upper substrate 112 may be disposed to be in contact with the lower substrate 111, the first plate pattern 121, the first line pattern 122, and the connection lines 181 and 182.

The upper substrate 112 may be formed of the same material as the lower substrate 111. For example, the upper substrate 112 may be formed of a silicon rubber such as polydimethylsiloxane (PDMS) or an elastomer such as polyurethane (PU) or polytetrafluoroethylene (PTFE) and thus have a flexible property. However, the material of the upper substrate 112 is not limited thereto.

Even though not illustrated in FIG. 3, a polarization layer may be disposed on the upper substrate 112. The polarization layer may perform a function which polarizes light incident from the outside of the display device 100 to reduce the external light reflection. Further, an optical film other than the polarization layer may be disposed on the upper substrate 112.

The filling layer 190 may be disposed on the entire surface of the lower substrate 111 to be filled between the components disposed on the upper substrate 112 and the lower substrate 111. The filling layer 190 may be configured by a curable adhesive. Specifically, the material which configures the filling layer 190 is coated on the entire surface of the lower substrate 111 and then is hardened so that the filling layer 190 may be disposed between the components disposed on the upper substrate 112 and the lower substrate 111. For example, the filling layer 190 may be an optically clear adhesive (OCA) and may be configured by an acrylic adhesive, a silicon-based adhesive, and a urethane-based adhesive.

### Circuit Structure and Driving Method of Active Area

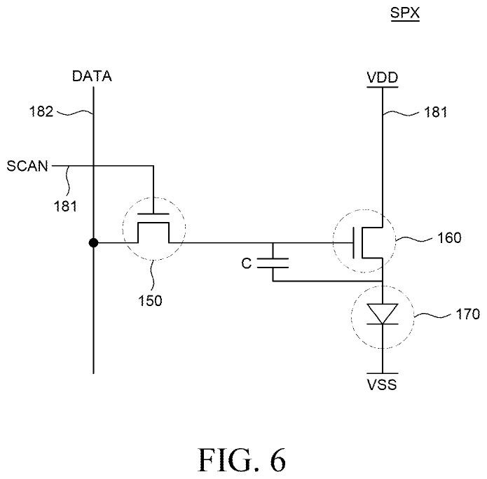

FIG. 6 is a circuit diagram of a sub pixel of a display device according to an example embodiment of the present disclosure.

Hereinafter, for the convenience of description, a structure and an operation when a sub pixel SPX of a display device according to the example embodiment of the present disclosure is a pixel circuit with 2T (transistor) 1C (capacitor) will be described, but the present disclosure is not limited thereto.

Referring to FIGS. 3 and 6, a sub pixel SPX of the display device according to the example embodiment of the present disclosure may be configured to include a switching transistor 150, a driving transistor 160, a storage capacitor C, and an LED 170.

The switching transistor 150 applies a data signal DATA supplied through the second connection line 182 to the driving transistor 160 and the storage capacitor C in accordance with a gate signal SCAN supplied through the first connection line 181.

A gate electrode 151 of the switching transistor 150 is electrically connected to the first connection line 181, a source electrode 153 of the switching transistor 150 is connected to the second connection line 182, and a drain electrode 154 of the switching transistor 150 is connected to the gate electrode 161 of the driving transistor 160.

The driving transistor 160 may operate so as to allow a driving current in accordance with the high potential power VDD supplied through the first connection line 181 and the data voltage DATA to flow in response to the data voltage DATA stored in the storage capacitor C.

A gate electrode 161 of the driving transistor 160 is electrically connected to the drain electrode 154 of the switching transistor 150, a source electrode of the driving transistor 160 is connected to the first connection line 181, and a drain electrode 164 of the driving transistor 160 is connected to the LED 170.

The LED 170 may operate to emit light in accordance with a driving current formed by the driving transistor 160. As described above, the n-electrode 174 of the LED 170 is connected to the first connection line 181 to be applied with the low potential power VSS. The p-electrode 174 of the LED 170 is connected to the drain electrode 164 of the driving transistor 160 to be applied with a driving voltage corresponding to the driving current.

As described above, the sub pixel SPX of the display device according to the example embodiment of the present disclosure is configured by a 2T1C structure including the switching transistor 150, the driving transistor 160, the storage capacitor C, and the LED 170. However, when a compensation circuit is added, the sub pixel may be configured in various ways, such as 3T1C, 4T2C, 5T2C, 6T1C, 6T2C, 7T1C, or 7T2C.

As described above, the display device according to the example embodiment of the present disclosure may include a plurality of sub pixels on a first substrate which is a rigid substrate, and each of the plurality of sub pixels SPX may include a switching transistor, a driving transistor, a storage capacitor, and an LED.

Accordingly, the display device according to the example embodiment of the present disclosure may not only be stretched by the lower substrate, but also include a pixel circuit with a 2T1C structure on each first substrate to emit light according to the data voltage in accordance with each gate timing.

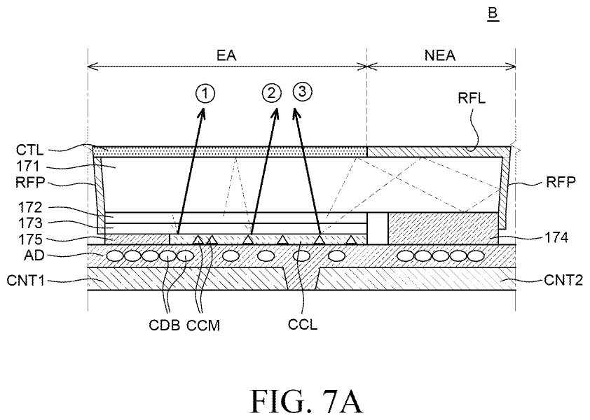

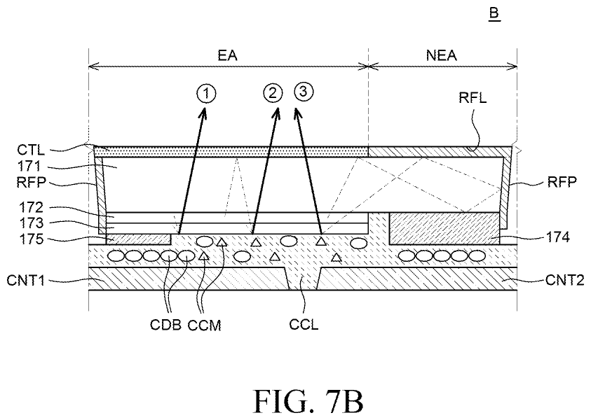

FIGS. 7A and 7B are enlarged cross-sectional views of an area B illustrated in FIG. 3.

Referring to FIG. 7A, the display device according to the example embodiment of the present disclosure may include an LED 170, a color conversion layer CCL, a color transmission layer CTL, a total reflection layer RFL, a total reflection pattern RFP, and an adhesive layer AD.

The LED 170 includes an n-type layer 171, an active layer 172, a p-type layer 173, an n-electrode 174, and a p-electrode 175. The LED 170 of the display device 100 according to the example embodiment of the present disclosure has a flip-chip structure in which the n-electrode 174 and the p-electrode 175 are formed on a lower surface.

The n-type layer 171 may be formed by injecting an n-type impurity into gallium nitride (GaN) having excellent crystallinity. The n-type layer 171 may be disposed on a separate base substrate which is formed of a material which is capable of emitting light.

The active layer 172 is disposed below a partial area of the n-type layer 171. The active layer 172 is a light emitting layer which emits light in the LED 170 and may be formed of a nitride semiconductor, for example, indium gallium nitride (InGaN).

That is, the light is generated upwardly and downwardly in the active layer 172. Therefore, a partial area of the LED 170 which overlaps the active layer 172 may be defined as an emission area EA and the other area of the LED 170 which does not overlap the active layer 172 may be defined as a non-emission area NEA.

The p-type layer 173 is disposed below the active layer 172. The p-type layer 173 may be formed by injecting a p-type impurity into gallium nitride (GaN).

The LED 170 according to the example embodiment of the present disclosure is manufactured by sequentially laminating the n-type layer 171, the active layer 172, and the p-type layer 173, and then etching the n-type layer 171, the active layer 172, and the p-type layer 173 laminated in the non-emission area NEA, and then forming the n-electrode 174 and the p-electrode 175. At this time, a predetermined part is etched to expose a part of the n-type layer 171 disposed in the non-emission area NEA. In other words, the surfaces of the LED 170 on which the n-electrode 174 and the p-electrode 175 are disposed are not flat surfaces, but have different heights.

As described above, the n-electrode 174 is disposed in the non-emission area NEA and may be formed of a conductive material. The p-electrode 175 is disposed in the emission area EA and may also be formed of a conductive material. For example, the n-electrode 174 is disposed below the n-type layer 171 which is exposed by the etching process and the p-electrode 175 is disposed below the p-type layer 173. In other words, it can be described that the p-electrode 175 and the n-electrode 174 are disposed below the n-type layer 171. Further, the p-electrode 175 may be formed of the same material as the n-electrode 174.

In other words, the placement relationship of the LED 170 can be summarized that the active layer 172, the p-type layer 173, and the p-electrode 175 are disposed in the emission area EA of the LED 170 and the n-electrode 174 is disposed in the non-emission area NEA of the LED 170. Further, the n-type layer 171 is disposed in both the emission area EA and the non-emission area NEA.

The color conversion layer CCL converts a wavelength of incident light and reflects the incident light. The color conversion layer CCL is disposed below the emission area EA of the LED 170. Specifically, the color conversion layer CCL may be disposed in an area between the p-electrode 175 and the n-electrode 174. Therefore, the color conversion layer CCL converts a wavelength of light generated from the active layer 172 and then reflects the light or converts a wavelength of light reflected from the color transmission layer CTL, the total reflection pattern RFP, and the total reflection layer RFL and then reflects the light.

That is, when a wavelength of the incident light of the color conversion layer CCL is referred to as a first wavelength and a wavelength of reflected light of the color conversion layer CCL is referred to as a second wavelength, the color conversion layer CCL converts light with the first wavelength into light with the second wavelength and then reflect the light. The above-described first wavelength may be lower than the second wavelength. That is, the incident light may be converted into reflected light having a lower energy by the color conversion layer CCL. The second wavelength may be a region excluding a wavelength band of 450 to 495 nm corresponding to the first wavelength, from the wavelength band of the visible ray. However, the present disclosure is not limited thereto and the first wavelength indicates a region of a specific wavelength band in the visible ray and the second wavelength may be defined as a wavelength band excluding the first wavelength band from the wavelength band of the visible ray. Therefore, the first wavelength may be to any one wavelength band of red light, blue light, and green light and the second wavelength is a wavelength band excluding the one wavelength band.

The color conversion layer CCL may be a film in which color conversion materials (CCM) are dispersed in an insulating film.

The color conversion material CCM may be a fluorescent dye which has a nanometer size which does not cause Rayleigh scattering and shows an excellent optical characteristic after forming a film for the patterning process, that is, has a high peak wavelength and a high intensity. For example, a yellow conversion material CCM may be a coumarin-based or perylene-based fluorescent dye. In contrast, the color conversion material CCM may be a quantum dot which is a semiconductor nano crystal having a nanometer size and has an energy band gap varying depending on the size and the shape, and has an excellent emission characteristic and a narrow emission line width. The quantum dot may include a core nano crystal and a shell nano crystal which encloses the core nano crystal. For example, the quantum dot may include at least one material of a group II compound semiconductor, a group III compound semiconductor, a group V compound semiconductor, and a group VI compound semiconductor. To be more specific, the core nano crystal may include CdSe, InGaP, CdTe, CdS, ZnSe, ZnTe, ZnS, HgTe, or HgS. Further, the shell nano crystal may include CuZnS, CdSe, CdTe, CdS, ZnSe, ZnTe, ZnS, HgTe, or HgS. A diameter of the quantum dot may have a range of 1 nm to 10 nm.

The color transmission layer CTL reflects light having a specific wavelength and transmits light having the other wavelength. Specifically, the color transmission layer CTL is disposed on the emission area EA of the LED 170. That is, the color transmission layer CTL is disposed on the n-type layer 171 of the LED 170. Therefore, the color transmission layer CTL reflects only light having a specific wavelength, among the light of various wavelengths, to a lower portion where the LED 170 is disposed, and transmits light of the other wavelengths upwardly.

For example, the color transmission layer CTL may be configured by a lamination structure of aluminum oxide (Al2O3) and titanium oxide (TiO2). The color transmission layer CTL may reflect light having a wavelength band of 450 to 495 nm corresponding to the first wavelength to the lower portion where the LED 170 is disposed and may transmit light of a wavelength corresponding to the second wavelength to an emission direction. The second wavelength may be a region excluding a wavelength band of 450 to 495 nm corresponding to the first wavelength, from the wavelength band of the visible ray. However, the present disclosure is not limited thereto and the first wavelength may indicate a region of a specific wavelength band in the visible ray and the second wavelength may be defined as a wavelength band excluding the first wavelength band from the wavelength band of the visible ray. Therefore, the first wavelength may be to any one wavelength band of red light, blue light, and green light and the second wavelength is a wavelength band excluding the one wavelength band.

For example, the color transmission layer CTL may reflect blue light to the lower portion where the LED 170 is disposed and transmit light of wavelengths other than blue to the emission direction.

The total reflection layer RFL and the total reflection pattern RFP reflect light of all wavelengths. Therefore, the total reflection layer RFL and the total reflection pattern RFP may be formed of a metal member having a reflective characteristic. For example, each of the total reflection layer RFL and the total reflection pattern RFP may be any one of aluminum (Al), chrome (Cr), gold (Au), and copper (Cu) which are metals having a high reflectivity or an alloy of two or more of them, or a multi-layer thereof, but is not limited thereto.

The total reflection layer RFL is disposed on the non-emission area NEA of the LED 170. Therefore, the total reflection layer RFL may reflect all light traveling to the non-emission area NEA of the LED 170, among light generated from the active layer 172. Therefore, the light may not be transmitted above the non-emission area NEA of the LED 170.

The total reflection pattern RFP is disposed on a side surface of the LED 170. Therefore, the total reflection pattern RFP reflects all light traveling to the side surface of the LED 170, among light generated from the active layer 172. Therefore, the light may not be transmitted to the side surface of the LED 170.

Further, the first connection pad CNT1 and the second connection pad CNT2 which have been described above may also be configured by a metal having a high reflectivity. Therefore, the first connection pad CNT1 and the second connection pad CNT2 also serve to reflect the incident light of all the wavelengths.

The adhesive layer AD is disposed between the top surfaces of the first connection pad CNT1 and the second connection pad CNT2 and the LED 170 so that the LED 170 may be bonded onto the first connection pad CNT1 and the second connection pad CNT2. In this case, the n-electrode 174 may be disposed on the second connection pad CNT2 and the p-electrode 175 may be disposed on the first connection pad CNT1.

The adhesive layer AD may be a conductive adhesive layer in which conductive balls CDB are dispersed in an insulating base member. Therefore, when heat or a pressure is applied to the adhesive layer AD, the conductive balls CDB are electrically connected in a portion applied with the heat or pressure to have a conductive property and an area which is not pressurized may have an insulating property. For example, the n-electrode 174 is electrically connected to the second connection pad CNT2 by means of the adhesive layer AD and the p-electrode 175 is electrically connected to the first connection pad CNT1 by means of the adhesive layer AD. That is, after applying the adhesive layer AD on the top surface of the second connection pad CNT2 and the first connection pad CNT1 using an inkjet method, the LED 170 is transferred onto the adhesive layer AD and the LED 170 is pressurized and heated. By doing this, the first connection pad CNT1 is electrically connected to the p-electrode 175 and the second connection pad CNT2 is electrically connected to the n-electrode 174. However, the remaining part of the adhesive layer AD excluding a part of the adhesive layer AD disposed between the n-electrode 174 and the second connection pad CNT2 and a part of the adhesive layer AD disposed between the p-electrode 175 and the first connection pad CNT1 have an insulating property. In the meantime, the adhesive layer AD may be divided to be disposed on the first connection pad CNT1 and the second connection pad CNT2, respectively.

In some example embodiments, as illustrated in FIG. 7B, the color conversion layer CCL may be a conductive adhesive layer in which the conductive balls CDB and the color conversion materials CCM are dispersed in the insulating base member.

Therefore, the color conversion layer CCL may be filled not only in an area between the n-electrode 174 and the p-electrode 175 of the LED 170, but also in all the areas between the n-electrode 174 and the p-type layer 173 and the active layer 172.

Therefore, as described above, the color conversion layer CCL converts a wavelength of light generated from the active layer 172 and then reflects the light or converts a wavelength of light reflected from the color transmission layer CTL, the total reflection pattern RFP, and the total reflection layer RFL and then reflects the light again.

Further, the color conversion layer CCL includes conductive balls CDB, so that as illustrated above, the color conversion layer CCL may electrically connect the first connection pad CNT1 and the p-electrode 175 and electrically connect the second connection pad CNT2 and the n-electrode 174.

However, a part of the color conversion layer CCL disposed between the n-electrode 174 and the second connection pad CNT2 and the remaining part of the color conversion layer CCL excluding the part of the color conversion layer CCL disposed between the p-electrode 175 and the first connection pad CNT1 have an insulating property.

Hereinafter, a reflection path of light of a display device according to an example embodiment of the present disclosure will be described with reference to FIGS. 7A and 7B.

In FIGS. 7A and 7B, a dotted line indicates light of blue colors having a relatively low wavelength and a solid line indicates light of red colors having a relatively high wavelength. However, a specific wavelength of the light is not limited thereto so that the colors may vary depending on the premise that the dotted line indicates light having a relatively low wavelength and the solid line indicates light having a relatively high wavelength.

Referring to a first arrow (1) in FIGS. 7A and 7B, blue light is generated below the LED 170 in the active layer 172. In the color conversion layer CCL, the blue light is converted into red light and is reflected toward the color transmission layer CTL. In the color transmission layer CTL, the red light is transmitted upwardly in the emission area EA of the LED 170.

Referring to a second arrow (2) in FIGS. 7A and 7B, blue light is generated above the LED 170 in the active layer 172. In the color transmission layer CTL, the blue light is reflected below the LED 170. In the color conversion layer CCL, the blue light is converted into red light and is reflected toward the color transmission layer CTL. In the color transmission layer CTL, the red light is transmitted upwardly in the emission area EA of the LED 170.

Referring to a third arrow (3) in FIGS. 7A and 7B, blue light is generated above the LED 170 in the active layer 172. The blue light is reflected below the LED 170 via the total reflection layer RFL, the total reflection pattern RFP, the n-electrode 174, and the color transmission layer CTL. In the color conversion layer CCL, the blue light is converted into red light and is reflected toward the color transmission layer CTL. In the color transmission layer CTL, the red light is transmitted upwardly in the emission area EA of the LED 170.

As described above, the display device according to the example embodiment of the present disclosure may extract light generated in all directions in the active layer 172 of the LED 170 with a flip-chip structure to the emission area EA of the LED 170. Specifically, the light reflected from the color transmission layer CTL, the total reflection layer RFL, and the total reflection pattern RFP is reused by converting the wavelength in the color conversion layer CCL so that the luminous efficiency of the LED 170 may be improved.

Further, the color transmission layer CTL of the present disclosure transmits only light of a specific wavelength and reflects light of the other wavelengths so that the color purity of light generated in the emission area EA of the LED 170 may be improved.

Hereinafter, a display device according to another example embodiment of the present disclosure will be described. A display device according to another example embodiment of the present disclosure has a different placement relationship of the planarization layer and the LED 170 from the display device according to the example embodiment of the present disclosure so that the difference will be mainly described. The same parts of the display device according to the example embodiment of the present disclosure and the display device according to another example embodiment of the present disclosure use the same reference numerals.

### Another Example Embodiment of Present Disclosure

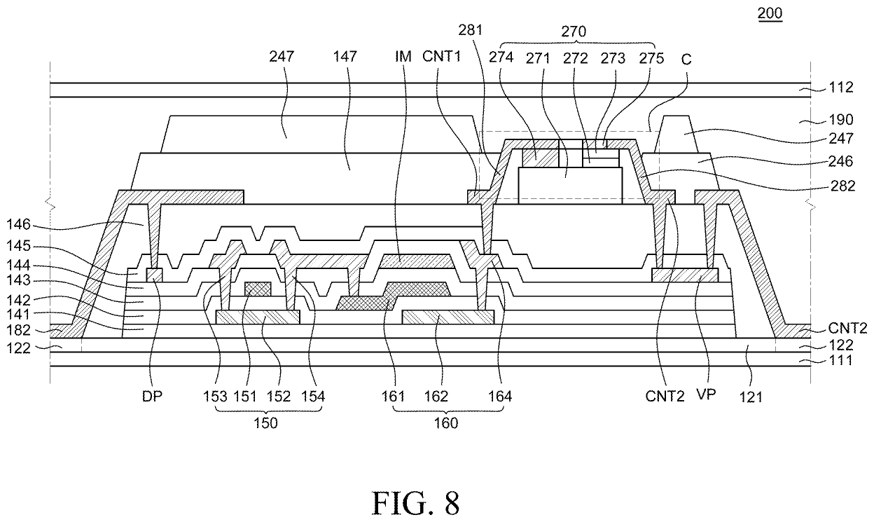

FIG. 8 is a cross-sectional view of a display device according to another example embodiment of the present disclosure.

Referring to FIG. 8, in a display device 200 according to another example embodiment of the present disclosure, an additional planarization layer 246 is formed on the first connection pad CNT1, the connection lines 181 and 182, and the planarization layer 146. The additional planarization layer 246 is disposed so as to cover at least a part of the first connection pad CNT1, the connection lines 181 and 182, and the planarization layer 146. Therefore, the additional planarization layer 246 planarizes at least a part of the first connection pad CNT1, the connection lines 181 and 182, and the planarization layer 146.

The additional planarization layer 246 may be configured by a single layer or a plurality of layers and may be formed of an organic material. Therefore, the additional planarization layer 246 may also be referred to as an organic insulating layer. For example, the additional planarization layer 246 may be formed of an acrylic organic material, but is not limited thereto.

A bank 247 is disposed on the additional planarization layer 246. The bank 247 is a component which divides adjacent sub pixels SPX.

The bank 247 may be formed of an insulating material. Further, the bank 247 may include a black material. The bank 247 includes the black material to block wiring lines which may be visible through the active area. For example, the bank 247 may be formed of a transparent carbon-based mixture and specifically, include carbon black. However, it is not limited thereto and the bank 247 may be formed of a transparent insulating material.

Referring to FIG. 8, the LED 170 which is connected to the first connection pad CNT1 and the second connection pad CNT2 is disposed in the additional planarization layer 246 and the bank 247.

The first connection pad CNT1 is electrically connected to the drain electrode 164 of the driving transistor 160 to be applied with a driving voltage from the driving transistor 160 to drive the LED 170. Even though in FIG. 8, it is illustrated that the first connection pad CNT1 is in direct contact with the drain electrode 164 of the driving transistor 160, the present disclosure is not limited thereto. Therefore, the first connection pad CNT1 and the drain electrode 164 of the driving transistor 160 may not be in direct contact with each other, but may be indirectly connected. Further, a low potential driving voltage is applied to the second connection pad CNT2 to drive the LED 170. Therefore, when the display device 100 is turned on, different voltage levels respectively applied to the first connection pad CNT1 and the second connection pad CNT2 are transmitted to the LED 170 so that the LED 170 emits light.

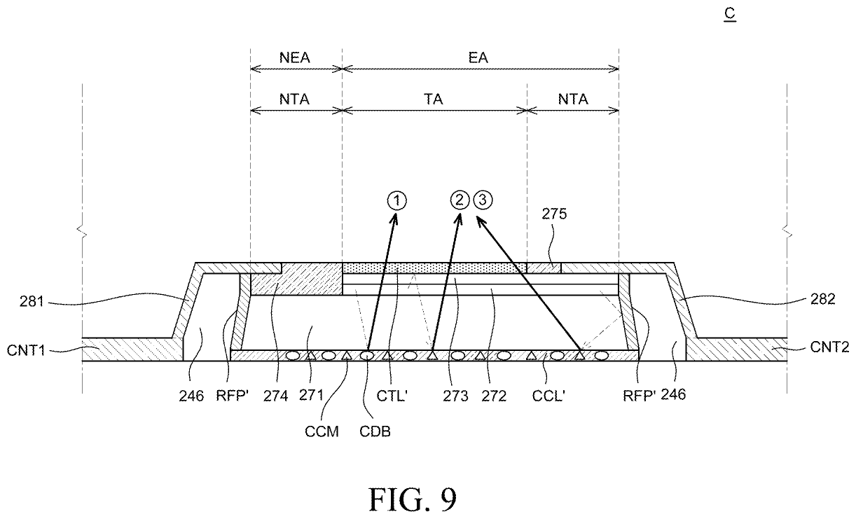

FIG. 9 is an enlarged cross-sectional view of an area C illustrated in FIG. 8.

Referring to FIG. 9, the display device according to another example embodiment of the present disclosure may include an LED 270, a color conversion layer CCL′, a color transmission layer CTL′, and a total reflection pattern RFP′.

The LED 270 includes an n-type layer 271, an active layer 272, a p-type layer 273, an n-electrode 274, and a p-electrode 275. The LED 270 of the display device 100 according to the example embodiment of the present disclosure has a lateral structure in which the n-electrode 274 and the p-electrode 275 are formed on an upper surface.

The n-type layer 271 may be formed by injecting an n-type impurity into gallium nitride (GaN) having excellent crystallinity. The n-type layer 271 may be disposed on a separate base substrate which is formed of a material which is capable of emitting light.

The active layer 272 is disposed on a partial area of the n-type layer 271. The active layer 272 is a light emitting layer which emits light in the LED 270 and may be formed of a nitride semiconductor, for example, indium gallium nitride (InGaN).

The p-type layer 273 is disposed on the active layer 272. The p-type layer 273 may be formed by injecting a p-type impurity into gallium nitride (GaN).

That is, the light is generated upwardly and downwardly in the active layer 272. Therefore, a partial area of the LED 270 which overlaps the active layer 272 may be defined as an emission area EA and the other area of the LED 270 which does not overlap the active layer 272 may be defined as a non-emission area NEA.

The LED 270 according to another example embodiment of the present disclosure is manufactured by sequentially laminating the n-type layer 271, the active layer 272, and the p-type layer 273, and then etching the n-type layer 271, the active layer 272, and the p-type layer 273 laminated in the non-emission area NEA, and then forming the n-electrode 274 and the p-electrode 275. At this time, a predetermined part is etched to expose a part of the n-type layer 271 disposed in the non-emission area NEA. In other words, the surfaces of the LED 270 on which the n-electrode 274 and the p-electrode 275 are disposed are not flat surfaces, but have different heights.

As described above, the n-electrode 274 is disposed in the non-emission area NEA and may be formed of a conductive material. The p-electrode 275 is disposed in a part of the emission area EA and may also be formed of a conductive material. For example, the n-electrode 274 is disposed on the n-type layer 271 which is exposed by the etching process and the p-electrode 275 is disposed on the p-type layer 273. In other words, it is described that the p-electrode 275 and the n-electrode 274 are disposed on the n-type layer 271. Further, the p-electrode 275 may be formed of the same material as the n-electrode 274.

The n-electrode 274 is electrically connected to the second connection pad CNT2 by means of a first additional connection line 281 disposed on the additional planarization layer 246. The p-electrode 275 is electrically connected to the first connection pad CNT1 by means of a second additional connection line 282 disposed on the additional planarization layer 246.

Therefore, the n-electrode 274 is applied with a low potential voltage by means of the first additional connection line 281 and the p-electrode 275 is applied with a driving voltage by means of the second additional connection line 282 so that the LED 270 may be driven in accordance with the driving voltage.

In other words, the placement relationship of the LED 270 may be summarized that the active layer 272, the p-type layer 273, and the p-electrode are disposed in the emission area EA of the LED 270 and the n-electrode 274 is disposed in the non-emission area NEA of the LED 270. Further, the n-type layer 271 is disposed in both the emission area EA and the non-emission area NEA.

The color conversion layer CCL′ converts a wavelength of incident light and reflects the incident light. The color conversion layer CCL′ is disposed below the LED 270. Specifically, the color conversion layer CCL′ may be disposed below the emission area EA and the non-emission area NEA of the LED 270. Therefore, the color conversion layer CCL′ converts a wavelength of light generated from the active layer 272 and then reflects the light or converts a wavelength of light reflected from the color transmission layer CTL′ and the total reflection pattern RFP′ and then reflects the light.

That is, when a wavelength of the incident light of the color conversion layer CCL′ is denoted as a first wavelength and a wavelength of reflected light of the color conversion layer CCL′ is denoted as a second wavelength, the color conversion layer CCL′ converts light with the first wavelength into light with the second wavelength and then reflect the light. The above-described first wavelength may be lower than the second wavelength. That is, the incident light may be converted into reflected light having a lower energy by the color conversion layer CCL′.

The color conversion layer CCL′ may be a conductive adhesive film in which conductive balls CDB and color conversion materials (CCM) are dispersed in an insulating film. Therefore, the color conversion layer CCL′ may serve to bond the n-type layer 271 of the LED 270.

As described above, when heat or a pressure is applied to the color conversion layer CCL′, the conductive balls CDB are electrically connected in a portion applied with the heat or pressure to have a conductive property, and an area which is not pressurized may have an insulating property. However, in the display device according to another example embodiment of the present disclosure, a heat or pressure process may be performed on the color conversion layer CCL′ depending on the necessity of the conduction.

The color transmission layer CTL′ reflects light having a specific wavelength and transmits light having the other wavelength. Specifically, the color transmission layer CTL′ is disposed on a partial area of the emission area EA of the LED 270 and is disposed between the n-electrode 274 and the p-electrode 275. Therefore, the color transmission layer CTL′ reflects only light having a specific wavelength, among light of various wavelengths, below the LED 270, and transmits light of the other wavelengths thereabove.

For example, the color transmission layer CTL′ may be configured by a lamination structure of aluminum oxide (Al2O3) and titanium oxide (TiO2). The color transmission layer CTL′ reflects light having a wavelength band of 450 to 495 nm corresponding to the first wavelength to the lower portion where the LED 270 is disposed and transmits light of a wavelength band corresponding to the second wavelength other than blue to an emission direction.

The color transmission layer CTL′ may be disposed only in a partial area of the emission area EA to transmit light. An area of the LED 270 in which the color transmission layer CTL′ is disposed may be referred to as a transmission area TA and an area in which the color transmission layer CTL′ is not disposed may be referred to as a non-transmission area NTA.

In summary, a partial area of the emission area EA of the LED 270 which overlaps the color transmission layer CTL′ may be referred to as a transmission area TA. An area of the emission area EA of the LED 270 in which the p-type layer 273 and the second additional connection line 282 are disposed may be referred to as a non-transmission area NTA. In the non-emission area NEA of the LED 270, light is not emitted so that the non-emission area may be referred to as a non-transmission area NTA.

The total reflection pattern RFP′ is disposed on a side surface of the LED 270. Therefore, the total reflection pattern RFP′ reflects all light traveling to the side surface of the LED 270, among light generated from the active layer 272. Therefore, the light cannot be transmitted to the side surface of the LED 270.

Therefore, the total reflection pattern RFP′ may be formed of a metal member having a reflective characteristic. For example, each total reflection pattern RFP′ may be any one of aluminum (Al), chrome (Cr), gold (Au), and copper (Cu) which are metals having a high reflectivity or an alloy of two or more of them, or a multi-layer thereof, but is not limited thereto.

Further, the first connection pad CNT1 and the second connection pad CNT2 which have been described above may also be configured by a metal having a high reflectivity. Therefore, the first connection pad CNT1 and the second connection pad CNT2 also serve to reflect the incident light of all the wavelengths. Further, the first additional connection line 281 and the second additional connection line 282 which have been described above may also be configured by a metal having a high reflectivity. Therefore, the first additional connection line 281 and the second additional connection line 282 also serve to reflect the incident light of all the wavelengths.

Hereinafter, a reflection path of light of a display device according to another example embodiment of the present disclosure will be described with reference to FIG. 9.

In FIG. 9, a dotted line indicates light of blue colors having a relatively low wavelength and a solid line indicates light of red colors having a relatively high wavelength. However, a specific wavelength of the light is not limited thereto so that the colors may vary depending on the premise that the dotted line indicates light having a relatively low wavelength and the solid line indicates light having a relatively high wavelength.

Referring to a first arrow (1) in FIG. 9, blue light is generated below the LED 270 in the active layer 272. In the color conversion layer CCL′, the blue light is converted into red light and is reflected toward the color transmission layer CTL′. In the color transmission layer CTL′, the red light is transmitted upwardly in the emission area EA of the LED 270.

Referring to a second arrow (2) in FIG. 9, blue light is generated above the LED 270 in the active layer 272. In the color transmission layer CTL′, the blue light is reflected below the LED 270. In the color conversion layer CCL′, the blue light is converted into red light and is reflected toward the color transmission layer CTL′. In the color transmission layer CTL′, the red light is transmitted upwardly in the emission area EA of the LED 270.

Referring to a third arrow (3) in FIG. 9, blue light is generated below the LED 270 in the active layer 272. The blue light is reflected below the LED 270 via the total reflection pattern RFP′ and the color transmission layer CTL′. In the color conversion layer CCL′, the blue light is converted into red light and is reflected toward the color transmission layer CTL′. In the color transmission layer CTL′, the red light is transmitted upwardly in the emission area EA of the LED 270.

As described above, the display device according to another example embodiment of the present disclosure may extract light generated in all directions in the active layer of the LED 270 with a lateral structure to the emission area EA of the LED 270. Specifically, the light reflected from the color transmission layer CTL′ and the total reflection pattern RFP′ is reused by converting the wavelength in the color conversion layer CCL′ so that the luminous efficiency of the LED 270 may be improved.

Further, the color transmission layer CTL′ of the present disclosure transmits only light of a specific wavelength and reflects light of the other wavelengths so that the color purity of light generated in the emission area EA of the LED 270 may be improved.

The example embodiments of the present disclosure can also be described as follows:

According to an aspect of the present disclosure, a display device includes a stretchable lower substrate; a pattern layer which is disposed on the lower substrate and is configured by a plurality of plate patterns and a plurality of line patterns; a plurality of pixels which is disposed on each of the plurality of plate patterns; and a plurality of connection lines which is disposed on each of the plurality of line patterns and connects the plurality of pixels, each of the plurality of pixels includes a light emitting diode and a driving element which drives the light emitting diode, the light emitting diode is divided into an emission area in which light is emitted and a non-emission area in which light is not emitted, a color conversion layer is disposed below the emission area of the light emitting diode, and a color transmission layer is disposed on the emission area of the light emitting diode, thereby improving the luminous efficiency of the light emitting diode.

The color conversion layer may convert light having a first wavelength emitted from the light emitting diode into light having a second wavelength.

The color transmission layer may transmit only the light having a second wavelength reflected from the color conversion layer and may reflect the light having a first wavelength emitted from the light emitting diode.

The first wavelength may be to a wavelength of incident light of the color conversion layer and the second wavelength is a wavelength of reflected light of the color conversion layer.

A total reflection layer that reflects light may be disposed on the non-emission area of the light emitting diode.

A total reflection pattern which reflects light may be disposed on a side surface of the light emitting diode.

The color conversion layer may be a conductive adhesive layer in which conductive balls and color conversion materials may be dispersed in an insulating base member.

The color conversion layer is a film in which color conversion materials are dispersed in an insulating film.

The light emitting diode may include an n-type layer, an active layer, a p-type layer, an n-electrode, and a p-electrode, the active layer, the p-type layer, and the p-electrode may be disposed in the emission area, the n-electrode is disposed in the non-emission area, and the n-type layer is disposed in the emission area and the non-emission area.

The light emitting diode may be a flip-chip type and the p-electrode and the n-electrode are disposed below the n-type layer.

The color transmission layer may be disposed on the n-type layer.

The color conversion layer may be disposed between the p-electrode and the n-electrode.

The light emitting diode may be a lateral type and the p-electrode and the n-electrode are disposed on the n-type layer.

The color conversion layer may be disposed below the n-type layer.

The color transmission layer may be disposed between the p-electrode and the n-electrode.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a stretchable lower substrate;
a pattern layer disposed on the lower substrate, the pattern layer including a plurality of plate patterns and a plurality of line patterns;
a plurality of pixels disposed on each of the plurality of plate patterns; and
a plurality of connection lines disposed on each of the plurality of line patterns and connected to the plurality of pixels,
wherein each of the plurality of pixels includes a light emitting diode and a driving element configured to drive the light emitting diode, the light emitting diode having an emission area in which light is emitted and a non-emission area in which light is not emitted, a color conversion layer is disposed below the emission area of the light emitting diode, and a color transmission layer is disposed on the emission area of the light emitting diode.

2. The display device according to claim 1, wherein the color conversion layer converts light having a first wavelength emitted from the light emitting diode into light having a second wavelength.

3. The display device according to claim 2, wherein the color transmission layer transmits only the light having a second wavelength reflected from the color conversion layer and reflects the light having a first wavelength emitted from the light emitting diode.

4. The display device according to claim 3, wherein the first wavelength is a wavelength of incident light of the color conversion layer and the second wavelength is a wavelength of reflected light of the color conversion layer.

5. The display device according to claim 1, wherein a total reflection layer that reflects light is disposed on the non-emission area of the light emitting diode.

6. The display device according to claim 1, wherein a total reflection pattern which reflects light is disposed on a side surface of the light emitting diode.

7. The display device according to claim 1, wherein the color conversion layer is a conductive adhesive layer in which conductive balls and color conversion materials are dispersed in an insulating base member.

8. The display device according to claim 1, wherein the color conversion layer is a film in which color conversion materials are dispersed in an insulating film.

9. The display device according to claim 1, wherein the light emitting diode includes an n-type layer, an active layer, a p-type layer, an n-electrode, and a p-electrode, the active layer, the p-type layer, and the p-electrode are disposed in the emission area, the n-electrode is disposed in the non-emission area, and the n-type layer is disposed in the emission area and the non-emission area.

10. The display device according to claim 9, wherein the light emitting diode is a flip-chip type and the p-electrode and the n-electrode are disposed below the n-type layer.

11. The display device according to claim 10, wherein the color transmission layer is disposed on the n-type layer.

12. The display device according to claim 10, wherein the color conversion layer is disposed between the p-electrode and the n-electrode.

13. The display device according to claim 9, wherein the light emitting diode is a lateral type and the p-electrode and the n-electrode are disposed on the n-type layer.

14. The display device according to claim 13, wherein the color conversion layer is disposed below the n-type layer.

15. The display device according to claim 13, wherein the color transmission layer is disposed between the p-electrode and the n-electrode.
